(19) United States
(12) Patent Application Publication
(10) Pub. No.: US 2024/0387416 A1
(43) Pub. Date: Nov. 21, 2024

(54) SEMICONDUCTOR DEVICE

(71) Applicant: Sumitomo Electric Industries, Ltd., Osaka (JP)

(72) Inventor: Koji TSUKASHIMA, Osaka-shi (JP)

(73) Assignee: Sumitomo Electric Industries, Ltd., Osaka (JP)

(21) Appl. No.: 18/612,588

(22) Filed: Mar. 21, 2024

(30) Foreign Application Priority Data
May 19, 2023 (JP) 2023-083195

(51) Int. Cl. H01L 23/66; H03F 1/02; H03F 1/56

(52) U.S. Cl. CPC H01L 23/66; H03F 1/0288; H03F 1/565; H01L 2223/6611; H01L 2223/6655; H03F 2200/451

(57) ABSTRACT

A semiconductor device includes a first semiconductor chip having a first amplifier and a first output pad, a second semiconductor chip having a second amplifier, a third semiconductor chip having a third amplifier and a second output pad, a fourth semiconductor chip having a fourth amplifier, a passive element chip including a first matching circuit connected between the first amplifier and the second amplifier, a second matching circuit connected between the third amplifier and the fourth amplifier, a first input pad electrically connected to the first output pad, and a second input pad electrically connected to the second output pad, wherein a distance between the first input pad and the second input pad in a second direction intersecting the first direction is shorter than a distance between the first output pad and the second output pad in the second direction.

### CROSS REFERENCE TO RELATED APPLICATIONS

This application claims priority based on Japanese Patent Application No. 2023-083195 filed on May 19, 2023, and the entire contents of the Japanese patent applications are incorporated herein by reference.

### FIELD

The present disclosure relates to a semiconductor device.

### BACKGROUND

An amplifier in which two amplifiers are provided in parallel, such as a Doherty amplifier, is known as an amplifier that amplifies a high frequency signal such as a microwave. It is known that the two amplifiers connected in parallel are each provided with two stage amplifiers (for example, US Patent Application Publication No. 2022/0123693).

### SUMMARY

A semiconductor device according to the present disclosure includes: a first semiconductor chip having a first amplifier and a first output pad that outputs a first high frequency signal output from the first amplifier; a second semiconductor chip having a second amplifier to which the first high frequency signal is input; a third semiconductor chip having a third amplifier and a second output pad that outputs a second high frequency signal output from the third amplifier; a fourth semiconductor chip having a fourth amplifier to which the second high frequency signal is input; and a passive element chip including: a first matching circuit connected between the first amplifier and the second amplifier and arranged between the first semiconductor chip and the second semiconductor chip in a first direction; a second matching circuit connected between the third amplifier and the fourth amplifier and arranged between the third semiconductor chip and the fourth semiconductor chip in the first direction; a first input pad electrically connected to the first output pad; and a second input pad electrically connected to the second output pad; wherein a distance between the first input pad and the second input pad in a second direction intersecting the first direction is shorter than a distance between the first output pad and the second output pad in the second direction.

A semiconductor device according to the present disclosure includes: a first semiconductor chip having a first amplifier and a first output pad that outputs a first high frequency signal output from the first amplifier; a second semiconductor chip having a second amplifier to which the first high frequency signal is input; a third semiconductor chip having a third amplifier and a second output pad that outputs a second high frequency signal output from the third amplifier; a fourth semiconductor chip having a fourth amplifier to which the second high frequency signal is input; a passive element chip including: a first matching circuit connected between the first amplifier and the second amplifier and arranged between the first semiconductor chip and the second semiconductor chip in a first direction; a second matching circuit connected between the third amplifier and the fourth amplifier and arranged between the third semiconductor chip and the fourth semiconductor chip in the first direction; a first input pad electrically connected to the first output pad; a second input pad electrically connected to the second output pad; and a reference potential pad provided between the first input pad and the second input pad and supplied with a reference potential; a first bonding wire electrically connecting the first output pad to the first input pad; a second bonding wire electrically connecting the second output pad to the second input pad; and a third bonding wire provided between the first bonding wire and the second bonding wire, the third bonding wire having a first end electrically connected to the reference potential and a second end electrically connected to the reference potential pad.

### BRIEF DESCRIPTION OF DRAWINGS

FIG. 1 is a circuit diagram of an amplifier circuit according to a first embodiment.

FIG. 2 is a plan view of a semiconductor device according to the first embodiment.

FIG. 3 is a cross-sectional view of the semiconductor device according to the first embodiment.

FIG. 4 is a plan view of a semiconductor device according to a first comparative example.

FIG. 5 is a plan view of a semiconductor device according to a second embodiment.

FIG. 6 is a plan view illustrating an example of a circuit according to the second embodiment.

FIG. 7 is a plan view illustrating an example of a circuit according to the second embodiment.

FIG. 8 is a plan view illustrating an example of a circuit according to the second embodiment.

FIG. 9 is a plan view illustrating an example of a circuit according to the second embodiment.

FIG. 10 is a plan view of the vicinity of an IPD according to a first modification of the second embodiment.

FIG. 11 is a plan view of a semiconductor device according to a third embodiment.

FIG. 12 is a plan view of a part of an IPD according to the third embodiment.

FIG. 13 is a circuit diagram of the part of the IPD according to the third embodiment.

### DETAILED DESCRIPTION OF EMBODIMENTS

A matching circuit and a bias circuit are provided between the two stage amplifiers. When a single integrated passive device (IPD) is used as passive elements of the matching circuits and the bias circuits between two sets of the two stages amplifiers connected in parallel, the Doherty amplifier can be reduced in size. However, the reduction in size of the Doherty amplifier is not sufficient. In addition, the signals of two sets of the two stage amplifiers connected in parallel may interfere with each other.

The present disclosure has been made in view of the above problems, and an object thereof is to reduce the size of the semiconductor device or suppress the interference of signals.

### DETAILS OF EMBODIMENTS OF THE PRESENT DISCLOSURE

First, the contents of the embodiments of this disclosure are listed and explained.
(1) A semiconductor device according to the present disclosure includes: a first semiconductor chip having a first amplifier and a first output pad that outputs a first high frequency signal output from the first amplifier; a second semiconductor chip having a second amplifier to which the first high frequency signal is input; a third semiconductor chip having a third amplifier and a second output pad that outputs a second high frequency signal output from the third amplifier; a fourth semiconductor chip having a fourth amplifier to which the second high frequency signal is input; and a passive element chip including: a first matching circuit connected between the first amplifier and the second amplifier and arranged between the first semiconductor chip and the second semiconductor chip in a first direction; a second matching circuit connected between the third amplifier and the fourth amplifier and arranged between the third semiconductor chip and the fourth semiconductor chip in the first direction; a first input pad electrically connected to the first output pad; and a second input pad electrically connected to the second output pad; wherein a distance between the first input pad and the second input pad in a second direction intersecting the first direction is shorter than a distance between the first output pad and the second output pad in the second direction. This makes it possible to reduce the width of the passive element chip in the second direction and to reduce the width of the semiconductor device in the first direction. Therefore, the semiconductor device can be reduced in size.
(2) In the above (1), the passive element chip may include a third output pad that outputs the first high frequency signal to the second amplifier, and a fourth output pad that outputs the second high frequency signal to the fourth amplifier. The first input pad may be arranged in a region closer to the second matching circuit than a first straight line extending in the first direction through a center of the third output pad in the second direction, and the second input pad may be arranged in a region closer to the first matching circuit than a second straight line extending in the first direction through a center of the fourth output pad in the second direction. This makes it possible to reduce the width of the passive element chip in the second direction.
(3) In the above (1) or (2), the passive element chip may include: a first bias pad to which a first bias voltage supplied to at least one of the first amplifier and the second amplifier is supplied and that is arranged at a first end of the passive element chip in the second direction; and a second bias pad to which a second bias voltage supplied to at least one of the third amplifier and the fourth amplifier is supplied and that is arranged at a second end of the passive element chip in the second direction. This makes it possible to reduce the width of the passive element chip in the second direction.
(4) In the above (3), the first bias pad may be arranged in a region closer to the first semiconductor chip than a center line passing through a center of the passive chip in the first direction, and the second bias pad may be arranged in a region closer to the third semiconductor chip than the center line. This makes it possible to reduce the width of the passive element chip in the second direction.
(5) In any one of the above (1) to (4), the semiconductor device further may include: a first bonding wire electrically connecting the first output pad to the first input pad; a second bonding wire electrically connecting the second output pad to the second input pad; and a third bonding wire provided between the first bonding wire and the second bonding wire, the third bonding wire having a first end electrically connected to a reference potential. The passive element chip may include a reference potential pad provided between the first input pad and the second input pad and connected to a second end of the third bonding wire. This makes it possible to suppress interference of signals between the first input pad and the second input pad and between the first bonding wire and the second bonding wire, and to improve the isolation characteristics.
(6) In the above (5), the passive element chip may include a path electrically connecting the reference potential pad to the reference potential, the path being different from the third bonding wire. This makes it possible to further suppress the interference of signals.
(7) In the above (5), the passive element chip may include a capacitor having a first end electrically connected to the reference potential pad and a second end electrically connected to the reference potential via another path different from the third bonding wire. This makes it possible to further suppress the interference of signals.
(8) In the above (7), a resonance frequency of the third bonding wire and the capacitor may be located within an operating band of the first amplifier and the third amplifier. This makes it possible to further suppress the interference of signals.
(9) In the above (7) or (8), the passive element chip may include a resistor connected in series with the capacitor between the reference potential pad and the reference potential. This makes it possible to further suppress the interference of signals.
(10) In any one of the above (1) to (9), the first amplifier and the second amplifier may include a main amplifier of a Doherty amplifier, and the third amplifier and the fourth amplifier may include a peak amplifier of the Doherty amplifier. This makes it possible to reduce the size of the Doherty amplifier or suppress the interference of the signals.
(11) A semiconductor device according to the present disclosure includes: a first semiconductor chip having a first amplifier and a first output pad that outputs a first high frequency signal output from the first amplifier; a second semiconductor chip having a second amplifier to which the first high frequency signal is input; a third semiconductor chip having a third amplifier and a second output pad that outputs a second high frequency signal output from the third amplifier; a fourth semiconductor chip having a fourth amplifier to which the second high frequency signal is input; a passive element chip including: a first matching circuit connected between the first amplifier and the second amplifier and arranged between the first semiconductor chip and the second semiconductor chip in a first direction; a second matching circuit connected between the third amplifier and the fourth amplifier and arranged between the third semiconductor chip and the fourth semiconductor chip in the first direction; a first input pad electrically connected to the first output pad; a second input pad electrically connected to the second output pad; and a reference potential pad provided between the first input pad and the second input pad and supplied with a reference potential; a first bonding wire electrically connecting the first output pad to the first input pad; a second bonding wire electrically connecting the second output pad to the second input pad; and a third bonding wire provided between the first bonding wire and the second bonding wire, the third bonding wire having a first end electrically connected to the reference potential and a second end electrically connected to the reference potential pad. This makes it possible to suppress the interference of signals between the first input pad and the second input pad and between the first bonding wire and the second bonding wire.
(12) In the above (11), the passive element chip may include a path electrically connecting the reference potential pad to the reference potential, the path being different from the third bonding wire. This makes it possible to further suppress the interference of signals.
(13) In the above (11), the passive element chip may include a capacitor having a first end electrically connected to the reference potential pad and a second end electrically connected to the reference potential via another path different from the third bonding wire. This makes it possible to further suppress the interference of signals.
(14) In the above (13), a resonance frequency of the third bonding wire and the capacitor may be located within an operating band of the first amplifier and the third amplifier. This makes it possible to further suppress the interference of signals.
(15) In the above (13) or (14), the passive element chip may include a resistor connected in series with the capacitor between the reference potential pad and the reference potential. This makes it possible to further suppress the interference of signals.
(16) In any one of the above (11) to (15), the first amplifier and the second amplifier may include a main amplifier of a Doherty amplifier, and the third amplifier and the fourth amplifier may include a peak amplifier of the Doherty amplifier. This makes it possible to reduce the size of the Doherty amplifier or suppress the interference of the signals.

Specific examples of a semiconductor device according to embodiments of the present disclosure will be described below with reference to the drawings. It should be noted that the present disclosure is not limited to these examples, but is defined by the claims and is intended to include all modifications within the meaning and scope equivalent to the claims.

### First Embodiment

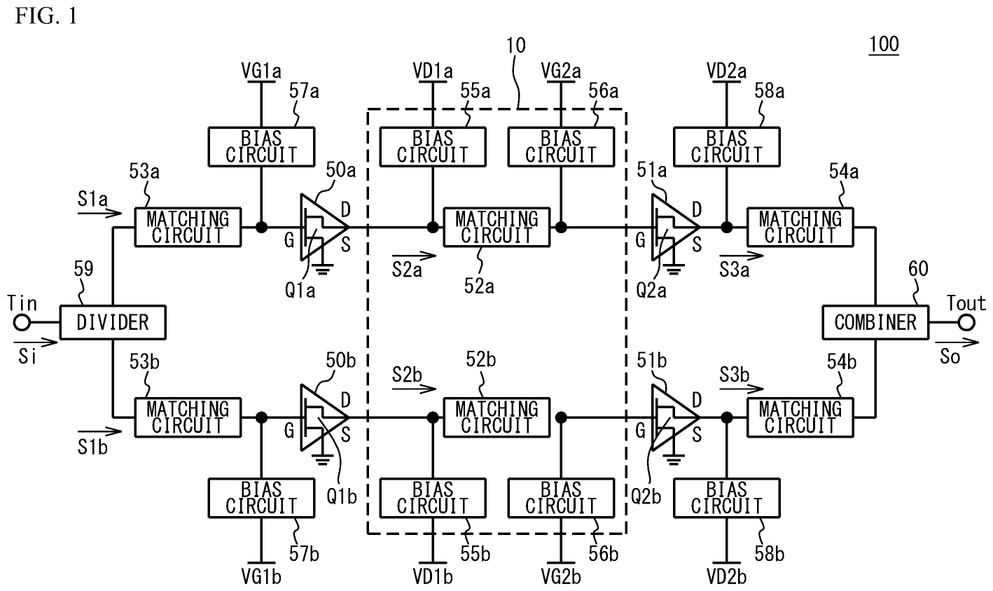

A semiconductor device used in a Doherty amplifier will be described as an example of a semiconductor device. FIG. 1 is a circuit diagram of an amplifier circuit according to a first embodiment. As illustrated in FIG. 1, in an amplifier circuit 100 of the first embodiment, amplifiers 50a and 51a and amplifiers 50b and 51b are connected in parallel between an input terminal Tin and an output terminal Tout. A peak amplifier is two stage amplifiers including the amplifiers 50a and 51a, and a main amplifier is two stage amplifiers including amplifiers 50b and 51b. The amplifiers 50a and 50b are driver amplifiers, and the amplifiers 51a and 51b are power amplifiers. When the amplifier circuit 100 is used in a base station for mobile communications, the frequency of the high frequency signal input to the input terminal Tin is, for example, 0.5 GHZ to 10 GHZ.

A divider 59 divides an input signal Si input to the input terminal Tin into signals S1a and S1b. The amplifier 50a amplifies the signal S1a input via a matching circuit 53a, and outputs the amplified signal as a signal S2a. The matching circuit 53a matches an impedance when the matching circuit 53a is seen from the divider 59 with an impedance when the amplifier 50a is seen from the matching circuit 53a. The amplifier 51a amplifies the signal S2a input via a matching circuit 52a, and outputs the amplified signal as a signal S3a. The matching circuit 52a matches an impedance when the matching circuit 52a is seen from the amplifier 50a with an impedance when the amplifier 51a is seen from the matching circuit 52a. The signal S3a is input to a combiner 60 via a matching circuit 54a. The matching circuit 54a matches an impedance when the matching circuit 54a is seen from the amplifier 51a with an impedance when the combiner 60 is seen from the matching circuit 54a.

The amplifier 50b amplifies the signal S1b input via a matching circuit 53b, and outputs the amplified signal as a signal S2b. The matching circuit 53b matches an impedance when the matching circuit 53b is seen from the divider 59 with an impedance when the amplifier 50b is seen from the matching circuit 53b. The amplifier 51b amplifies the signal S2b input via a matching circuit 52b, and outputs the amplified signal as a signal S3b. The matching circuit 52b matches an impedance when the matching circuit 52b is seen from the amplifier 50b with an impedance when the amplifier 51b is seen from the matching circuit 52b. The signal S3b is input to the combiner 60 via a matching circuit 54b. The matching circuit 54b matches an impedance when the matching circuit 54b is seen from the amplifier 51b with an impedance when the combiner 60 is seen from the matching circuit 54b. The combiner 60 combines the signals S3a and S3b and outputs the combined signal to the output terminal Tout as an output signal So.

The amplifiers 50a, 50b, 51a and 51b include transistors Q1a, Q1b, Q2a and Q2b, respectively. The transistors Q1a, Q1b, Q2a, and Q2b are, for example, FETs (Field Effect Transistors), and are, for example, GaN HEMTs (Gallium Nitride High Electron Mobility Transistors) or LDMOS (Laterally Diffused Metal Oxide Semiconductors). The sources S of the transistors Q1a, Q1b, Q2a and Q2b are connected to reference potentials such as ground. The gates G of the transistors Q1a, Q1b, Q2a, and Q2b input the signals S1a, S1b, S2a, and S2b, respectively. The drains D of the transistors Q1a, Q1b, Q2a, and Q2b output the signals S2a, S2b, S3a, and S3b, respectively.

Bias circuits 57a and 57b supply bias voltages VG1a and VG1b (gate bias voltages) to the amplifiers 50a and 50b, respectively, and suppress leakage of the signals S1a and S1b to the bias terminals, respectively. Bias circuits 55a and 55b supply bias voltages VD1a and VD1b (drain bias voltages) to the amplifiers 50a and 50b, respectively, and suppress leakage of the signals S2a and S2b to the bias terminals, respectively. Bias circuits 56a and 56b supply bias voltages VG2a and VG2b (gate bias voltages) to the amplifiers 51a and 51b, respectively, and suppress leakage of the signals S2a and S2b to the bias terminals, respectively. Bias circuits 58a and 58b supply bias voltages VD2a and VD2b (drain bias voltages) to the amplifiers 51a and 51b, respectively, and suppress leakage of the signals S3a and S3b to the bias terminals, respectively.

The matching circuits 52a and 52b and the bias circuits 55a, 55b, 56a and 56b are provided in an integrated passive device (IPD) 10.

The amplifier 51a performs a class C operation, and the amplifier 51b performs a class AB or class B operation. When an input power of the input signal Si is small, the amplifier 51b mainly amplifies the input signal Si. When the input power is increased, the amplifier 51a amplifies a peak of the input signal Si in addition to the amplifier 51b. The amplifiers 51a and 51b may have the same size (e.g., the same gate width), or the amplifier 51a may be larger than the amplifier 51b.

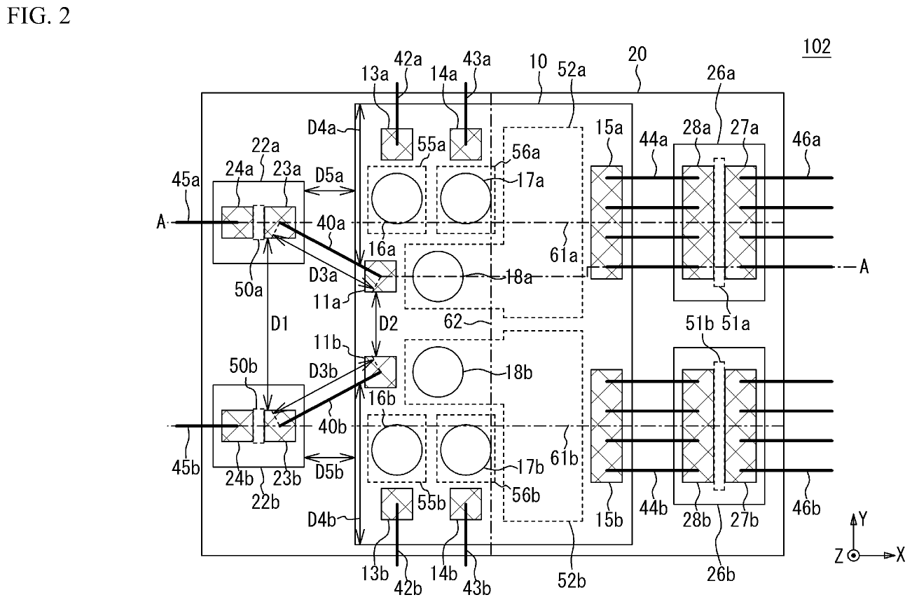

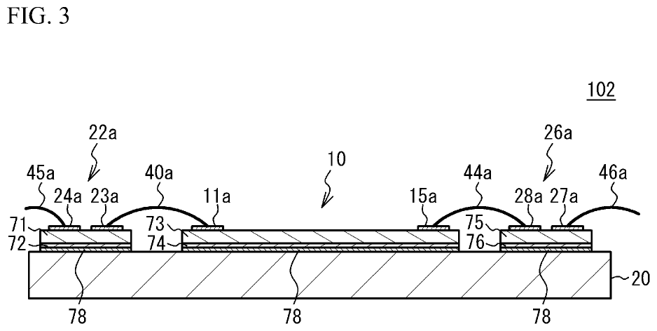

FIG. 2 is a plan view of a semiconductor device according to the first embodiment. FIG. 3 is a cross-sectional view of the semiconductor device according to the first embodiment, and a cross-sectional view taken along the line A-A in FIG. 2. A normal direction of a base 20 is defined as a Z direction. An arrangement direction of semiconductor chips 22a and 26a, and an arrangement direction of semiconductor chips 22b and 26b are defined as an X direction (first direction). An arrangement direction of the semiconductor chips 22a and 22b and an arrangement direction of the semiconductor chips 26a and 26b are defined as a Y direction (second direction intersecting the first direction). The X direction and the Y direction need not be perpendicular to each other, and may intersect with each other.

As illustrated in FIGS. 2 and 3, in a semiconductor device 102 of the first embodiment, the IPD10 and the semiconductor chips 22a, 22b, 26a, and 26b are mounted on the base 20. At least an upper surface of the base 20 is a conductor layer.

The IPD 10 includes a substrate 73. The matching circuits 52a and 52b and the bias circuits 55a, 55b, 56a and 56b are provided on the substrate 73. The matching circuits 52a and 52b and the bias circuits 55a, 55b, 56a and 56b have inductors 18a, 18b, 16a, 16b, 17a and 17b, respectively. Input pads 11a and 11b, output pads 15a and 15b, and bias pads 13a, 13b, 14a and 14b are provided on an upper surface of the IPD 10. An electrode 74 is provided on a lower surface of the substrate 73.

The semiconductor chips 22a and 22b include substrates 71, respectively. An output pad 23a and an input pad 24a are provided on an upper surface of the substrate 71 of the semiconductor chip 22a. The amplifier 50a is provided in the semiconductor chip 22a. An output pad 23b and an input pad 24b are provided on an upper surface of the substrate 71 of the semiconductor chip 22b. The amplifier 50b is provided in the semiconductor chip 22b. Electrodes 72 are provided on lower surfaces of the substrates 71, respectively.

The semiconductor chips 26a and 26b include substrates 75, respectively. An output pad 27a and an input pad 28a are provided on an upper surface of the substrate 75 of the semiconductor chip 26a. The amplifier 51a is provided in the semiconductor chip 26a. An output pad 27b and an input pad 28b are provided on an upper surface of the substrate 75 of the semiconductor chip 26b. The amplifier 51b is provided in the semiconductor chip 26b. Electrodes 76 are provided on lower surfaces of the substrates 75, respectively.

The electrode 74 of the IPD10, the electrodes 72 of the semiconductor chips 22a and 22b, and the electrodes 76 of the semiconductor chips 26a and 26b are bonded to the upper surface of the base 20 by a bonding layer 78 made of a metal paste, a brazing material, or the like.

Bonding wire 40a electrically connects the output pad 23a to the input pad 11a. Bonding wire 40b electrically connects the output pad 23b to the input pad 11b. Bonding wire 42a electrically connects the bias pad 13a to a terminal (not illustrated) that supplies the bias voltage VD1a. Bonding wire 42b electrically connects the bias pad 13b to a terminal (not illustrated) that supplies the bias voltage VD1b. Bonding wire 43a electrically connects the bias pad 14a to a terminal (not illustrated) that supplies the bias voltage VG2a. Bonding wire 43b electrically connects the bias pad 14b to a terminal (not illustrated) that supplies the bias voltage VG2b.

Bonding wires 44a electrically connect the output pad 15a to the input pad 28a. Bonding wires 44b electrically connect the output pad 15b to the input pad 28b. Bonding wire 45a electrically connects the input pad 24a to a terminal (not illustrated) that outputs the signal S1a. Bonding wire 45b electrically connects the input pad 24b to a terminal (not illustrated) that outputs the signal S1b. Bonding wires 46a electrically connect the output pad 27a to a terminal (not illustrated) to which the signal S3a is input. Bonding wires 46b electrically connect the output pad 27b to a terminal (not illustrated) to which the signal S3b is input.

As described above, in the semiconductor device 102, the semiconductor chip 22a (first semiconductor chip) has the amplifier 50a (first amplifier) and the output pad 23a (first output pad) that outputs the signal S2a (first high frequency signal) output from the amplifier 50a. The semiconductor chip 26a (second semiconductor chip) has the amplifier 51a (second amplifier) to which the signal S2a (first high frequency signal) is input. The semiconductor chip 22b (third semiconductor chip) includes the amplifier 50b (third amplifier) and the output pad 23b (second output pad) that outputs a signal S2b (second high frequency signal) output from the amplifier 50b. The semiconductor chip 26b (fourth semiconductor chip) has the amplifier 51b (fourth amplifier) to which the signal S2b (second high frequency signal) is input. The first semiconductor chip 22a and the third semiconductor chip 22b may be integrated into a single semiconductor chip, or the second semiconductor chip 26a and the fourth semiconductor chip 26b may be integrated into a single semiconductor chip.

The single IPD 10 (passive element chip) is arranged between the semiconductor chips 22a and 22b and the semiconductor chips 26a and 26b in the X direction. The IPD 10 includes the matching circuit 52a (first matching circuit) connected between the amplifiers 50a and 51a, and the matching circuit 52b (second matching circuit) connected between the amplifiers 50b and 51b. The IPD 10 further includes the input pad 11a (first input pad) electrically connected to the output pad 23a via the bonding wire 40a, and the input pad 11b (second input pad) electrically connected to the output pad 23b via the bonding wire 40b.

The IPD 10 includes the output pad 15a (third output pad), the output pad 15b (fourth output pad), the bias pads 13a and 14a (first bias pad), and the bias pads 13b and 14b (second bias pad). The output pad 15a is electrically connected to the amplifier 51a. The output pad 15b is electrically connected to the amplifier 51b. The bias voltages (first bias voltages) supplied to the amplifiers 50a and 51a are supplied to the bias pads 13a and 14a. The bias voltages (second bias voltages) supplied to the amplifiers 50b and 51b are supplied to the bias pads 13b and 14b.

Straight lines passing through the centers of the output pads 15a and 15b in the Y direction and extending in the X direction are denoted by 61a and 61b. The center line of the IPD10 in the X direction is defined as a straight line 62. A distance between the output pads 23a and 23b is defined as D1, and a distance between the input pads 11a and 11b is defined as D2. The lengths of the bonding wires 40a and 40b are defined as D3a and D3b, respectively. In the first embodiment, the distance D2 is shorter than the distance D1.

The substrate 73 of the IPD10 is a semiconductor substrate or an insulator substrate such as a silicon substrate or an alumina substrate. Passive elements such as capacitors, inductors, resistors, wirings, and pads are provided on the substrate 71. When the transistors Q1a, Q1b, Q2a, and Q2b are GaN HEMTs, the substrates 71 of the semiconductor chips 22a and 22b and the substrates 75 of the semiconductor chips 26a and 26b are, for example, silicon carbide (SIC) substrates, sapphire substrates, or gallium nitride (GaN) substrates. When the transistors Q1a, Q1b, Q2a and Q2b are LDMOS, the substrates 71 and 75 are silicon substrates. The bonding wires 40a, 40b, 42a, 42b, 43a, 43b, 44a, 44b, 45a, 45b are, for example, aluminum wires or gold wires. The upper surface of the base 20 is a conductive layer such as copper.

### First Comparative Example

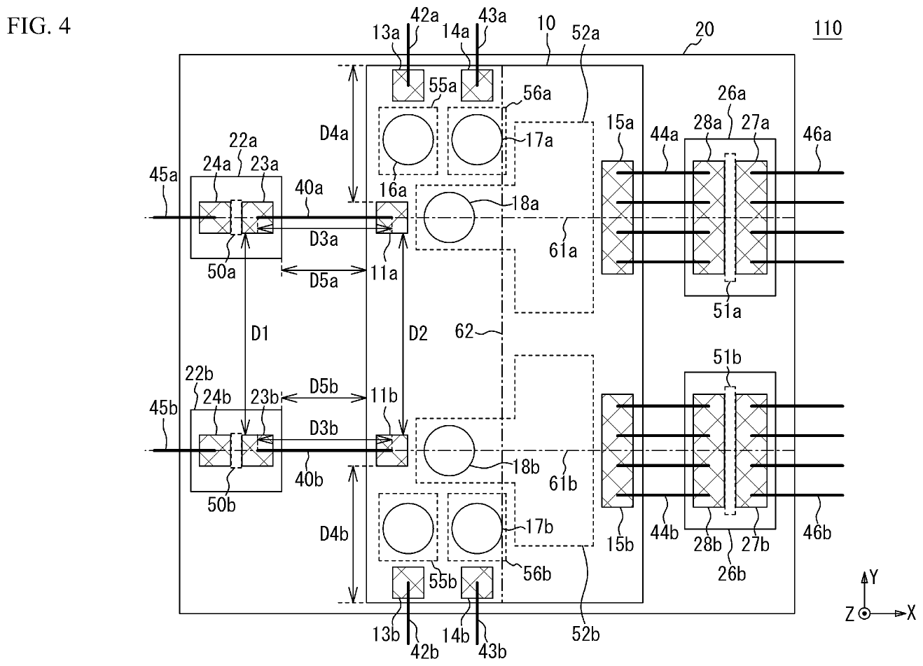

FIG. 4 is a plan view of a semiconductor device according to a first comparative example. As illustrated in FIG. 4, in a semiconductor device 110 of the first comparative example, the distances D1 and D2 are substantially equal to each other. The output pad 23a, the input pad 11a, and the output pad 15a are positioned approximately on the straight line 61a. The output pad 23b, the input pad 11b, and the output pad 15b are positioned approximately on the straight line 61b. The other configuration of the first comparative example is the same as that of the first embodiment.

### [Arrangement of Each Element in IPD]

The arrangement of the IPD 10 in the first embodiment and the first comparative example will be described. In two sets of the two stage amplifiers connected in parallel, the directions of the signals are the same, that is, the X direction. For this reason, on the upper surface of the IPD 10, the input pads 11a and 11b are provided in the vicinity of a −side (i.e., a left side in FIGS. 2 and 4) of the IPD10 in the X direction, and the output pads 15a and 15b are provided in the vicinity of a +side (i.e., a right side in FIGS. 2 and 4) of the IPD 10 in the X direction. For example, no other pads and elements (e.g. capacitors, inductors, resistors, and vias) are provided between the input pads 11a and 11b and the −side of the IPD 10 in the X direction. No other pads and elements (e.g. capacitors, inductors, resistors, and vias) are provided between the output pads 15a and 15b and the +side of the IPD 10 in the X direction. The bias voltages are supplied to the amplifiers 50a and 51a from the +direction in the Y direction, and the bias voltages are supplied to the amplifiers 50b and 51b from the −direction in the Y direction. For this reason, the bias pads 13a and 14a are provided in the vicinity of the +side of the IPD 10 in the Y direction, and the bias pads 13b and 14b are provided in the vicinity of the −side of the IPD10 in the Y direction.

In the matching circuits 52a and 52b, portions for matching output impedances of the amplifiers 50a and 50b with input impedances of the matching circuits 52a and 52b are provided in the vicinity of the input pads 11a and 11b, respectively. For example, the inductors 18a and 18b are provided in the vicinity of the input pads 11a and 11b, respectively. Portions for matching the input impedances of the amplifiers 51a and 51b with output impedances of the matching circuits 52a and 52b are provided in the vicinity of the output pads 15a and 15b, respectively. Input matching circuits of the amplifiers 51a and 51b have large areas. Therefore, a region of the IPD 10 closer to the output pads 15a and 15b than the straight line 62 is mostly occupied by the matching circuits 52a and 52b.

For this reason, the bias pads 13a, 13b, 14a and 14b are provided in regions closer to the input pads 11a and 11b than the straight line 62, respectively. The bias circuits 55a, 55b, 56a and 56b are provided in the vicinity of the bias pads 13a, 13b, 14a and 14b, respectively. Therefore, the input pads 11a and 11b are arranged relatively far from both sides of the IPD 10 in the Y direction. In order to suppress electromagnetic interference between the amplifiers 50a and 50b and between the amplifiers 51a and 51b, the distance between the semiconductor chips 22a and 22b and the distance between the semiconductor chips 26a and 26b are set at distances where the electromagnetic field interference does not occur.

In the semiconductor device 110 of the first comparative example, the distances D1 and D2 are substantially equal to each other under the above-described restrictions. When distances D4a and D4b between the input pads 11a and 11b and the both sides of the IPD 10 in the Y direction are secured, the width of the IPD 10 in the Y direction becomes wider, and hence the semiconductor device 110 is increased in size.

The bonding wires 40a and 40b may function as portions of matching circuits that match the output impedances of the amplifiers 50a and 50b in the semiconductor chips 22a and 22b with the input impedances of the matching circuits 52a and 52b. In this case, a length D3a of the bonding wire 40a and a length D3b of the bonding wire 40b are constant. In order to secure the lengths D3a and D3b, the distances D5a and D5b between the semiconductor chips 22a and 22b and the IPD 10 are secured, respectively. This increases the size of the semiconductor device 110.

### As to First Embodiment

According to the first embodiment, the distance D2 between the input pads 11a and 11b in the Y direction is shorter than the distance D1 between the output pads 23a and 23b in the Y direction. Thereby, as illustrated in FIG. 2, the matching circuits 52a and 52b can be brought closer to each other in the Y direction, and the width of the IPD 10 in the Y direction can be reduced. Further, the lengths D3a and D3b of the bonding wires 40a and 40b can be made the same as those of the first comparative example, and the distances D5a and D5b between the semiconductor chips 22a and 22b and the IDP 10 can be made shorter than those of the first comparative example. This allows the semiconductor device 102 to be reduced in size. The distance D2 may be 0.7 times or less the distance D1. If the distance D1 is too long, the semiconductor device is increased in size. From this viewpoint, the distance D2 can be set to be 0.1 times or more the distance D1. The distance D1 is, for example, 500 μm or more and 2000 μm or less, and the distance D2 is, for example, 200 μm or more and 1000 μm or less. The lengths D3a and D3b are, for example, 500 μm or more and 1500 μm or less.

The input pad 11a is arranged in a region closer to the matching circuit 52b than the straight line 61a (first straight line) extending in the X direction through the center of the output pad 15a in the Y direction. The input pad 11b is arranged in a region closer to the matching circuit 52a than the straight line 61b (second straight line) extending in the X direction through the center of the output pad 15b in the Y direction. Thus, even if the distances D4a and D4b of the first embodiment are the same as those of the first comparative example, the width of the IPD 10 in the Y direction can be reduced. The distances D4a and D4b are, for example, 1000 μm or more and 2000 μm or less.

The bias pads 13a and 14a are arranged at a first end of the IPD 10 that is +side in the Y direction. The bias pads 13b and 14b are arranged at a second end of the IPD 10 that is −side in the Y direction. When the bias pads 13a, 14a, 13b, and 14b are arranged in this manner, the bonding wires 42a, 43a, 42b, and 43b can be easily connected to the bias pads 13a, 14a, 13b, and 14b. However, the input pads 11a and 11b are provided with distances D4a and D4b from both sides of the IPD 10 in the Y direction. This makes it easy for the width of the IPD 10 in the Y direction to increase. Therefore, the distance D2 is set smaller than the distance D1. This makes it possible to reduce the width of the IPD 10 in the Y direction. It is sufficient that at least one of the bias pads 13a and 14a is arranged at the first end and at least one of the bias pads 13b and 14b is arranged at the second end. The pad being provided at the end of the IPD 10 means that no other pad or element (capacitor, inductor, resistor, or via) is provided between the pad and the side of the IPD 10.

The bias pads 13a and 14a are arranged in a first region closer to the semiconductor chip 22a than the straight line 62 of the center line in the X direction of the IPD 10, and the bias pads 13b and 14b are arranged in a second region closer to the semiconductor chip 22b than the straight line 62. When the bias pads 13a, 14a, 13b and 14b are arranged in this way, the matching circuits 52a and 52b can be arranged near the output pads 15a and 15b. However, the input pads 11a and 11b are provided with the distances D4a and D4b from both sides of the IPD 10 in the Y direction. Therefore, the distance D2 is set smaller than the distance D1. This can reduce the width of the IPD 10 in the Y direction. It is sufficient that at least one of the bias pads 13a and 14a (first bias pad) is arranged in the first region, and at least one of the bias pads 13b and 14b (second bias pad) is arranged in the second region.

### Second Embodiment

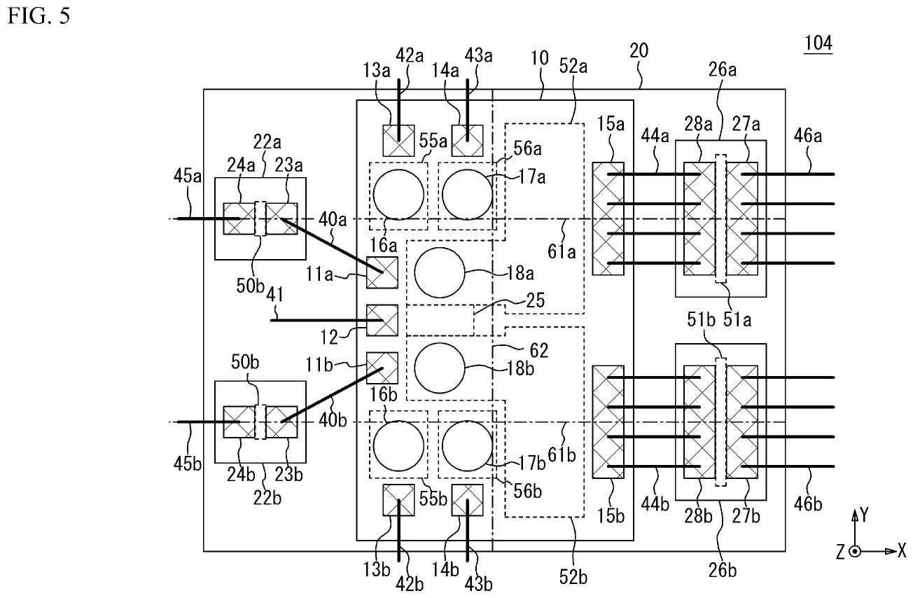

FIG. 5 is a plan view of a semiconductor device according to a second embodiment. As illustrated in FIG. 5, in a semiconductor device 104 of the second embodiment, a reference potential pad 12 is provided between the input pads 11a and 11b of the IPD 10. The bonding wire 40a (first bonding wire) electrically connects the output pad 23a to the input pad 11a. The bonding wire 40b (second bonding wire) electrically connects the output pad 23b to the input pad 11b. A bonding wire 41 (third bonding wire) is provided between the bonding wires 40a and 40b. A first end of the bonding wire 41 is electrically connected to the base 20, and a second end of the bonding wire 41 is electrically connected to the reference potential pad 12. As a result, the reference potential is supplied to the reference potential pad 12. The IDP 10 is provided with a circuit 25 electrically connected to the reference potential pad 12. The other configurations of the second embodiment are the same as those of the first embodiment, and the description thereof is omitted.

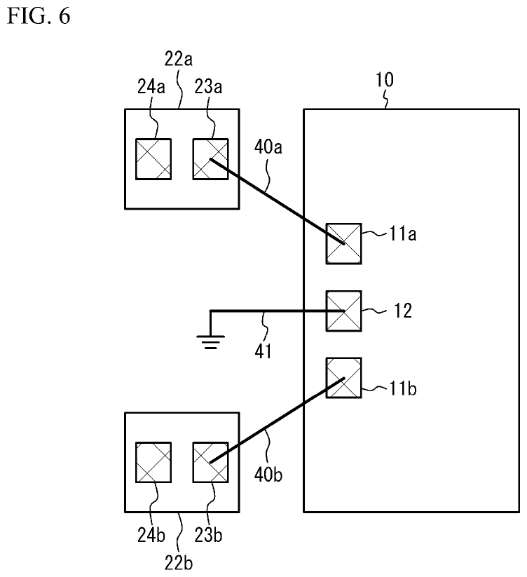

FIGS. 6, 7, 8 and 9 are plan views illustrating examples of a circuit according to the second embodiment. In FIGS. 6 to 9, the illustration of configuration except for the input pads 11a and 11b, the reference potential pad 12 and the circuit 25 in the IPD 10, and the semiconductor chips 22a and 22b is omitted. As illustrated in FIGS. 6 to 9, the first end of the bonding wire 41 is grounded via the base 20.

In the example of FIG. 6, the reference potential pad 12 is not electrically connected to any element other than the bonding wire 41. Since the reference potential pad 12 and the bonding wire 41 function as a shield, even if the distance D2 between the input pads 11a and 11b in the second embodiment is shorter than that in the first comparative example, the interference of signals between the input pad 11a and the bonding wire 40a and between the input pad 11b and the bonding wire 40b can be suppressed, and isolation characteristics can be improved.

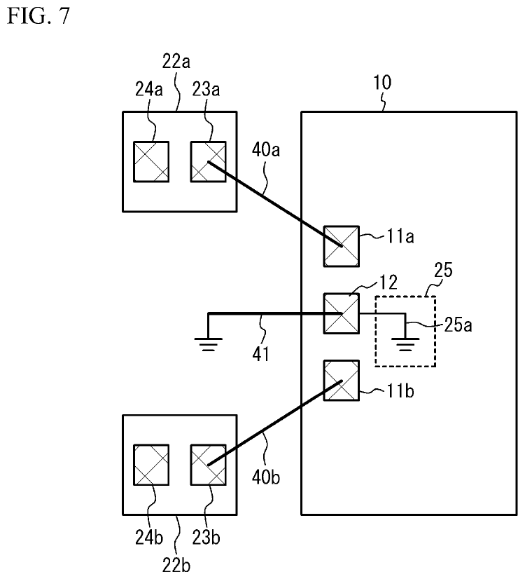

In the example of FIG. 7, the circuit 25 is provided in the IPD 10. The circuit 25 includes a path 25a for electrically connecting and short-circuiting the reference potential pad 12 to the reference potential, and the path 25a is different from the bonding wire 41 for electrically connecting and short-circuiting the reference potential pad 12 to the reference potential. This makes it possible to further improve the shield function of the reference potential pad 12 and the bonding wire 41, and to further suppress the interference of signals.

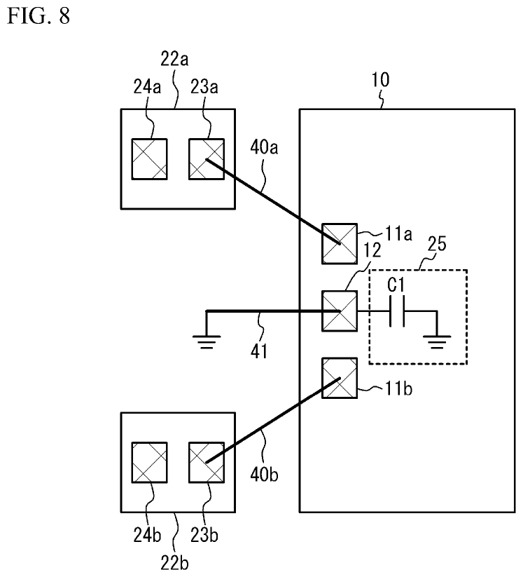

In the example of FIG. 8, the circuit 25 includes a capacitor C1 having a first end electrically connected to the reference potential pad 12 and a second end electrically connected to the reference potential via a path different from the bonding wire 41. A resonance frequency of a resonance circuit of the bonding wire 41 and the capacitor C1 is located within the operating band of the amplifiers 51a and 51b. As a result, the signals within the operating band radiated from the input pad 11a and the bonding wire 40a are reflected by the bonding wire 41 and the capacitor C1. The signals in the operating band radiated from the input pad 11b and the bonding wire 40b are reflected by the bonding wire 41 and the capacitor C1. Therefore, the interference of the signals between the input pads 11a and 11b and between the bonding wires 40a and 40b can be further suppressed.

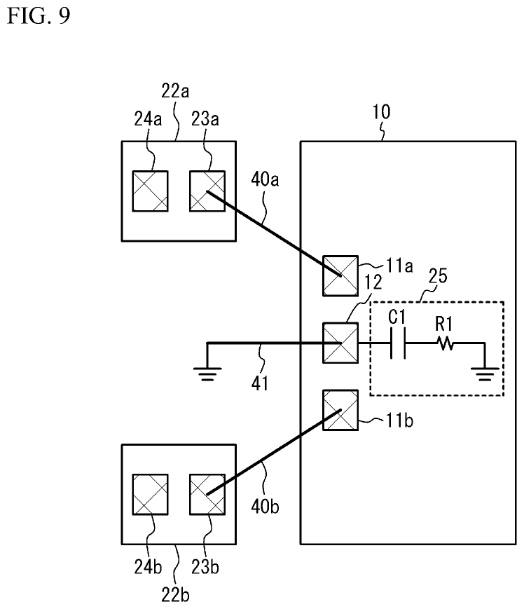

In the example of FIG. 9, the circuit 25 includes the capacitor C1 and a resistor R1 connected in series with the capacitor C1 between the reference potential pad 12 and the reference potential. A current flowing by the resonance of the bonding wire 41 and the capacitor C1 can be attenuated by the resistor R1. Therefore, the interference of the signal can be further suppressed.

### First Modification of Second Embodiment

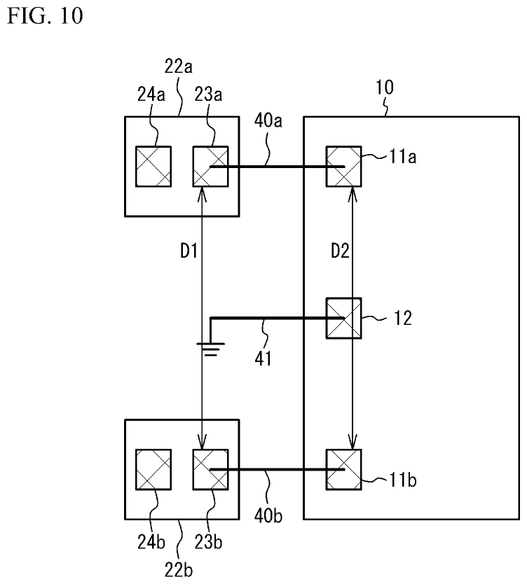

FIG. 10 is a plan view of the vicinity of the IPD in a first modification of the second embodiment. As illustrated in FIG. 10, the distance D1 between the output pads 23a and 23b and the distance D2 between the input pads 11a and 11b may be substantially equal to each other. Even when the distances D1 and D2 are substantially equal, the interference of the signals between the input pads 11a and 11b and between the bonding wires 40a and 40b can be suppressed by providing the reference potential pad 12 and the bonding wire 41. The circuit 25 in the example of FIGS. 7 to 9 may be provided. The other configurations of the first modification of the second embodiment are the same as those of the second embodiment, and the description thereof is omitted.

In the first and second embodiments and the modification thereof, the amplifiers 50a and 51a include the main amplifiers of the Doherty amplifier, and the amplifiers 50b and 51b include the peak amplifiers of the Doherty amplifier. The amplifiers 50a, 50b, 51a and 51b and the IPD 10 may be included in circuits other than the Doherty amplifier. Also in the circuits other than the Doherty amplifier, the circuits can be reduced in size or the interference of the signals can be suppressed.

### Third Embodiment

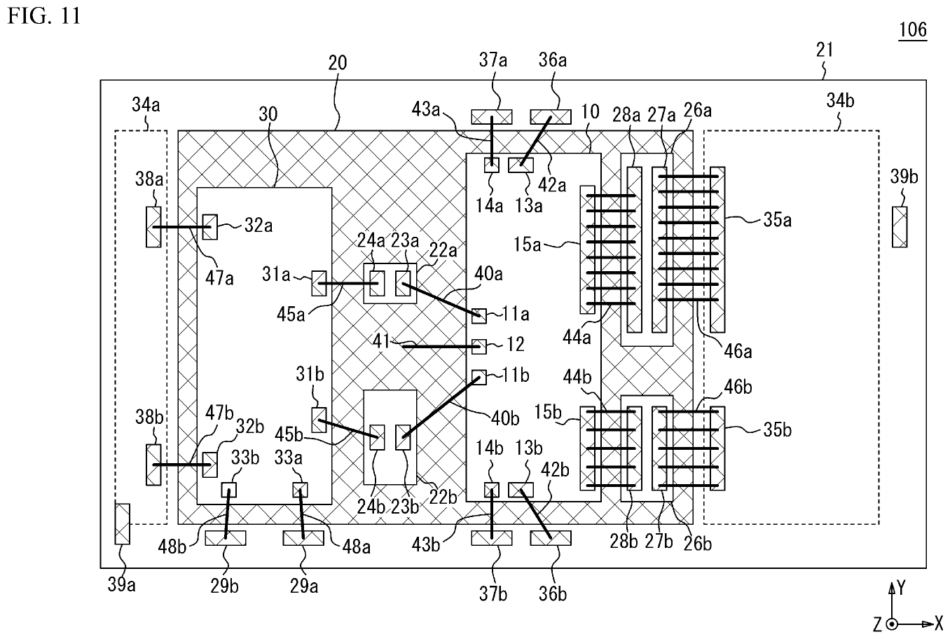

FIG. 11 is a plan view of a semiconductor device according to a third embodiment. As illustrated in FIG. 11, in a semiconductor device 106 of the third embodiment, the base 20 is provided on a substrate 21. The substrate 21 is a glass epoxy resin substrate such as a printed circuit board. The base 20 is a conductor layer provided on an upper surface of the substrate 21, and is, for example, a copper layer. The semiconductor chips 22a, 22b, 26a and 26b, and IPDs 10 and 30 are mounted on the base 20. Terminals 29a, 29b, 35a, 35b, 36a, 36b, 37a, 37b, 38a, 38b, 39a and 39b are provided on the upper surface of the substrate 21. Circuits 34a and 34b are formed on the substrate 21. Pads 31a, 31b, 32a, 32b, 33a and 33b are provided on an upper surface of the IPD 30.

The bonding wire 42a electrically connects the bias pad 13a to the terminal 36a. The bonding wire 42b electrically connects the bias pad 13b to the terminal 36b. The bonding wire 43a electrically connects the bias pad 14a to the terminal 37a. The bonding wire 43b electrically connects the bias pad 14b to the terminal 37b. The bonding wire 45a electrically connects the pad 31a to the pad 24a. The bonding wire 45b electrically connects the pad 31b to the pad 24b. The bonding wires 46a electrically connect the output pad 27a to the terminal 35a. The bonding wires 46b electrically connect the output pad 27b to the terminal 35b. Bonding wire 47a electrically connects the pad 32a to the terminal 38a. Bonding wire 47b electrically connects the pad 32b to the terminal 38b. Bonding wire 48a electrically connects the pad 33a to the terminal 29a. Bonding wire 48b electrically connects the pad 33b to the terminal 29b.

The circuit 34a includes the divider 59 of FIG. 1. The input signal Si input from the terminal 39a is divided into the signals S1a and S1b by the divider 59 of the circuit 34a.

The IPD30 includes the matching circuits 53a and 53b and the bias circuits 57a and 57b illustrated in FIG. 1. The signal S1a is input from the terminal 38a to the IPD 30 via the bonding wire 47a. The signal S1b is input from the terminal 38b to the IPD 30 via the bonding wire 47b. The bias voltage VG1a is supplied from the terminal 29a to the IPD 30 via the bonding wire 48a. The bias voltage VG1b is supplied from the terminal 29b to the IPD 30 via the bonding wire 48b. The signal S1a passed through the matching circuit 53a is input from the IPD 30 to the semiconductor chip 22a via the pad 31a and the bonding wire 45a. The signal S1b passed through the matching circuit 53b is input from the IPD 30 to the semiconductor chip 22b via the pad 31b and the bonding wire 45b.

The circuit 34b includes the matching circuits 54a and 54b, the bias circuits 58a and 58b, and the combiner 60 of FIG. 1. The signal S3a output from the semiconductor chip 26a is input to the circuit 34b via the bonding wires 46a and the terminal 35a. The signal S3b output from the semiconductor chip 26b is input to the circuit 34b via the bonding wires 46b and the terminal 35b. The output signal So obtained by combining the signal S3a passed through the matching circuit 54a and the signal S3b passed through the matching circuit 54b is output from the terminal 39b.

The operations of the semiconductor chips 22a, 22b, 26a and 26b and the IPD 10 of the third embodiment are the same as those of the first and second embodiments, and the description thereof will be omitted.

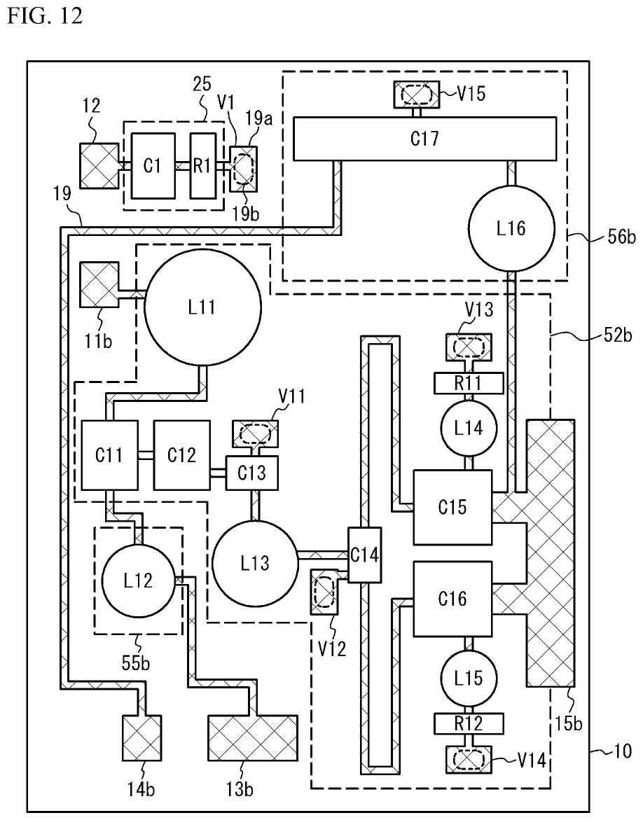

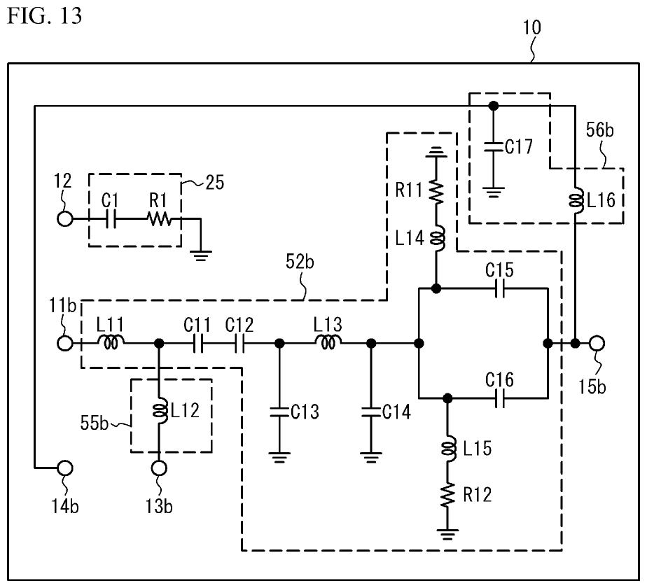

FIG. 12 is a plan view of a part of an IPD according to the third embodiment. FIG. 13 is a circuit diagram of the part of the IPD according to the third embodiment. As illustrated in FIG. 12, pads, capacitors, inductors, resistors, vias, and wirings 19 are provided on the IPD 10. The wirings 19 electrically connect the pads, the capacitors, the inductors, the resistors and the vias to each other. A via V1 has a pad 19a and a via hole 19b penetrating the IPD 10. As illustrated in FIGS. 12 and 13, the reference potential pad 12 is connected to the reference potential via the capacitor C1, the resistor R1 and the via V1 penetrating the IPD 10.

An inductor L11, capacitors C11 and C12, and an inductor L13 are connected in series between the input pad 11b and the output pad 15b, and capacitors C13 and C14 are shunt-connected via vias V11 and V12, respectively. Capacitors C15 and C16 are connected in parallel between the output pad 15b, and the inductor L13 and the capacitor C14. The inductor L14 and the resistor R11 are shunt-connected to a node between the capacitor C15 and the inductor L13 through a via V13. The inductor L15 and the resistor R12 are shunt-connected to a node between the capacitor C16 and the inductor L13 through a via V14. An inductor L12 is connected between the bias pad 13b and a node between the inductor L11 and the capacitor C11. An inductor L16 is connected in series between the bias pad 14b and the output pad 15b, and a capacitor C17 is shunt-connected between the bias pad 14b and the output pad 15b via a via V15.

The circuit 25 includes the capacitor C1 and the resistor R1. The matching circuit 52b includes the inductors L11, L13 to L15, the capacitors C11 to C16, and the resistors R11 and R12. The bias circuit 55b includes the inductor L12. The bias circuit 56b includes the inductor L16 and the capacitor C17. The operating bands of the amplifiers 50a, 50b, 51a, and 51b are, for example, 3.4 GHz to 4.0 GHz.

The embodiments disclosed here should be considered illustrative in all respects and not restrictive. The present disclosure is not limited to the specific embodiments described above, but various variations and changes are possible within the scope of the gist of the present disclosure as described in the claims.

What is claimed is:

1. A semiconductor device comprising:
a first semiconductor chip having a first amplifier and a first output pad that outputs a first high frequency signal output from the first amplifier;
a second semiconductor chip having a second amplifier to which the first high frequency signal is input;
a third semiconductor chip having a third amplifier and a second output pad that outputs a second high frequency signal output from the third amplifier;
a fourth semiconductor chip having a fourth amplifier to which the second high frequency signal is input; and
a passive element chip including:
a first matching circuit connected between the first amplifier and the second amplifier and arranged between the first semiconductor chip and the second semiconductor chip in a first direction;
a second matching circuit connected between the third amplifier and the fourth amplifier and arranged between the third semiconductor chip and the fourth semiconductor chip in the first direction;
a first input pad electrically connected to the first output pad; and
a second input pad electrically connected to the second output pad;
wherein a distance between the first input pad and the second input pad in a second direction intersecting the first direction is shorter than a distance between the first output pad and the second output pad in the second direction.

2. The semiconductor device according to claim 1, wherein
the passive element chip includes a third output pad that outputs the first high frequency signal to the second amplifier, and a fourth output pad that outputs the second high frequency signal to the fourth amplifier,
the first input pad is arranged in a region closer to the second matching circuit than a first straight line extending in the first direction through a center of the third output pad in the second direction, and
the second input pad is arranged in a region closer to the first matching circuit than a second straight line extending in the first direction through a center of the fourth output pad in the second direction.

3. The semiconductor device according to claim 1, wherein
the passive element chip includes:
a first bias pad to which a first bias voltage supplied to at least one of the first amplifier and the second amplifier is supplied and that is arranged at a first end of the passive element chip in the second direction; and
a second bias pad to which a second bias voltage supplied to at least one of the third amplifier and the fourth amplifier is supplied and that is arranged at a second end of the passive element chip in the second direction.

4. The semiconductor device according to claim 3, wherein
the first bias pad is arranged in a region closer to the first semiconductor chip than a center line passing through a center of the passive chip in the first direction, and
the second bias pad is arranged in a region closer to the third semiconductor chip than the center line.

5. The semiconductor device according to claim 1, further comprising:
a first bonding wire electrically connecting the first output pad to the first input pad;
a second bonding wire electrically connecting the second output pad to the second input pad; and
a third bonding wire provided between the first bonding wire and the second bonding wire, the third bonding wire having a first end electrically connected to a reference potential;
wherein the passive element chip includes a reference potential pad provided between the first input pad and the second input pad and connected to a second end of the third bonding wire.

6. The semiconductor device according to claim 5, wherein
the passive element chip includes a path electrically connecting the reference potential pad to the reference potential, the path being different from the third bonding wire.

7. The semiconductor device according to claim 5, wherein
the passive element chip includes a capacitor having a first end electrically connected to the reference potential pad and a second end electrically connected to the reference potential via another path different from the third bonding wire.

8. The semiconductor device according to claim 7, wherein
a resonance frequency of the third bonding wire and the capacitor is located within an operating band of the first amplifier and the third amplifier.

9. The semiconductor device according to claim 7, wherein
the passive element chip includes a resistor connected in series with the capacitor between the reference potential pad and the reference potential.

10. The semiconductor device according to claim 1, wherein
the first amplifier and the second amplifier include a main amplifier of a Doherty amplifier, and the third amplifier and the fourth amplifier include a peak amplifier of the Doherty amplifier.

11. A semiconductor device comprising:
a first semiconductor chip having a first amplifier and a first output pad that outputs a first high frequency signal output from the first amplifier;
a second semiconductor chip having a second amplifier to which the first high frequency signal is input;
a third semiconductor chip having a third amplifier and a second output pad that outputs a second high frequency signal output from the third amplifier;
a fourth semiconductor chip having a fourth amplifier to which the second high frequency signal is input;
a passive element chip including:
a first matching circuit connected between the first amplifier and the second amplifier and arranged between the first semiconductor chip and the second semiconductor chip in a first direction;
a second matching circuit connected between the third amplifier and the fourth amplifier and arranged between the third semiconductor chip and the fourth semiconductor chip in the first direction;
a first input pad electrically connected to the first output pad;
a second input pad electrically connected to the second output pad; and
a reference potential pad provided between the first input pad and the second input pad and supplied with a reference potential;
a first bonding wire electrically connecting the first output pad to the first input pad;
a second bonding wire electrically connecting the second output pad to the second input pad; and
a third bonding wire provided between the first bonding wire and the second bonding wire, the third bonding wire having a first end electrically connected to the reference potential and a second end electrically connected to the reference potential pad.

12. The semiconductor device according to claim 11, wherein
the passive element chip includes a path electrically connecting the reference potential pad to the reference potential, the path being different from the third bonding wire.

13. The semiconductor device according to claim 11, wherein
the passive element chip includes a capacitor having a first end electrically connected to the reference potential pad and a second end electrically connected to the reference potential via another path different from the third bonding wire.

14. The semiconductor device according to claim 13, wherein
a resonance frequency of the third bonding wire and the capacitor is located within an operating band of the first amplifier and the third amplifier.

15. The semiconductor device according to claim 13, wherein
the passive element chip includes a resistor connected in series with the capacitor between the reference potential pad and the reference potential.

16. The semiconductor device according to claim 11, wherein
the first amplifier and the second amplifier include a main amplifier of a Doherty amplifier, and the third amplifier and the fourth amplifier include a peak amplifier of the Doherty amplifier.
